(19) United States
(12) Patent Application Publication
(10) Pub. No.: US 2026/0230085 A1
(43) Pub. Date: Aug. 6, 2026

(54) DUAL DIGITAL-TO-ANALOG CONVERTER SWITCHING CONTROL CIRCUIT

(71) Applicant: STMicroelectronics International N.V., Geneva (CH)

(72) Inventors: Vaibhav GARG, Jagadhri (IN); Sanyam JAIN, Gautambudh Nagar (IN); Paras GARG, Noida (IN); Kallol CHATTERJEE, Kolkata (IN); Gauri MITTAL, Ghaziabad (IN)

(21) Appl. No.: 19/462,564

(22) Filed: Jan. 28, 2026

Related U.S. Application Data
(60) Provisional application No. 63/752,945, filed on Feb. 3, 2025.

(51) Int. Cl. H03M 1/66

(52) U.S. Cl. CPC H03M 1/662

(57) ABSTRACT

A dual digital-to-analog converter (DAC), a method using a dual DAC, and a continuous time sigma-delta analog-to-digital converter are provided. An example dual DAC includes a clock signal, a first DAC, a second DAC, and a DAC switching control circuit. The first DAC including a first switch and configured to generate a first analog output portion of the analog output signal during a high phase of the clock signal. The second DAC including a second switch and configured to generate a second analog output portion of the analog output signal during a low phase of the clock signal. The DAC switching control circuit configured to close the first switch during a first DAC settling portion of the low phase of the clock signal and open the first switch during a first DAC open portion of the low phase of the clock signal.

### CROSS-REFERENCE TO RELATED APPLICATIONS

This application claims the benefit of U.S. Provisional Patent Application No. 63/752,945, filed Feb. 3, 2025, the entire contents of which are hereby incorporated by reference in their entirety.

### TECHNOLOGICAL FIELD

Embodiments of the present disclosure relate generally to dual digital-to-analog converters, and more particularly, to switching control circuitry on a dual digital-to-analog converter.

### BACKGROUND

Various electronic systems require conversion between digital and analog signals. For example, many communication systems utilize digital signals on computing devices such as computers and smart phones and analog signals to transmit data between devices. Thus, electronic signals are continuously converted between analog and digital domains. A digital-to-analog converter (DAC) is an electronic device that converts digital signals into analog signals. Digital-to-analog converters may be designed for various types of operation, depending on the application. For example, a digital-to-analog converter may be designed as a non-return-to-zero digital-to-analog converter, a return-to-zero digital-to-analog converter, or a dual return-to-zero digital-to-analog converter. Each type of digital-to-analog converter includes various benefits and drawbacks that may be weighed based on the intended application.

Applicant has identified many technical challenges and difficulties associated with performing a digital-to-analog conversion at a dual digital-to-analog converter. Through applied effort, ingenuity, and innovation, Applicant has solved problems related to the digital-to-analog conversion at a dual digital-to-analog converter by developing solutions embodied in the present disclosure, which are described in detail below.

### BRIEF SUMMARY

Various embodiments are directed to an example dual digital-to-analog converter, a method for generating an analog output signal based on a digital input signal using a dual digital-to-analog converter, and a continuous time sigma-delta analog-to-digital converter including a dual digital-to-analog converter.

An example dual digital-to-analog converter configured to generate an analog output signal based on a digital input signal, may comprise a clock signal, a first digital-to-analog converter, a second digital-to-analog converter, and a DAC switching control circuit. The clock signal comprising a high phase and a low phase. The first digital-to-analog converter comprising a first switch, wherein the first digital-to-analog converter is configured to generate a first analog output portion of the analog output signal based on the digital input signal during the high phase of the clock signal. The second digital-to-analog converter comprising a second switch, wherein the second digital-to-analog converter is configured to generate a second analog output portion of the analog output signal based on the digital input signal during the low phase of the clock signal. The DAC switching control circuit configured to close the first switch during a first DAC settling portion of the low phase of the clock signal and open the first switch during a first DAC open portion of the low phase of the clock signal.

In some embodiments, the DAC switching control circuit is further configured to close the second switch during a second DAC settling portion of the high phase of the clock signal and open the second switch during a second DAC open portion of the high phase of the clock signal.

In some embodiments, the first DAC settling portion of the low phase of the clock signal is associated with a first settling time.

In some embodiments, the first settling time is associated with a time required to settle a first voltage on a first side of the first switch with a second voltage on a second side of the first switch.

In some embodiments, the first settling time is less than one-half of the low phase of the clock signal.

In some embodiments, the first DAC settling portion of the low phase of the clock signal is based on the clock signal and an inverted and delayed clock signal.

In some embodiments, the DAC switching control circuit is configured to generate the inverted and delayed clock signal by transmitting the clock signal through buffer circuitry configured to delay the clock signal by a buffer circuit delay.

In some embodiments, the buffer circuitry comprises an odd number of inverters.

In some embodiments, the DAC switching control circuit further comprises an OR gate configured to generate a first switch close signal, based on a logic OR operation of the clock signal and the inverted and delayed clock signal, wherein the first switch is closed based on the first switch close signal.

In some embodiments, the DAC switching control circuit is configured to generate an inverse switch close signal based on an inverse of the first switch close signal, wherein the first switch is closed based on the first switch close signal and the inverse switch close signal.

A method for generating an analog output signal based on a digital input signal is also provided. In some embodiments, the method comprises receiving, at a dual digital-to-analog converter, the digital input signal. The dual digital-to-analog converter comprising a first digital-to-analog converter and a second digital-to-analog converter. The method further comprises receiving, at the dual digital-to-analog converter, a clock signal comprising a high phase and a low phase. The method further comprises enabling the first digital-to-analog converter to generate a first analog output portion of the analog output signal based on the digital input signal during the high phase of the clock signal. The method further comprising enabling the second digital-to-analog converter to generate a second analog output portion of the analog output signal based on the digital input signal during the low phase of the clock signal. The method further comprising closing, by a DAC switching control circuit, a first switch associated with the first digital-to-analog converter during a first DAC settling portion of the low phase of the clock signal. The method further comprising opening, by the DAC switching control circuit, the first switch associated with the first digital-to-analog converter during a first DAC open portion of the low phase of the clock signal.

In some embodiments, the method further comprises closing, by the DAC switching control circuit, a second switch associated with the second digital-to-analog converter during a second DAC settling portion of the high phase of the clock signal; and opening, by the DAC switching control circuit, the second switch associated with the second digital-to-analog converter during a second DAC open portion of the high phase of the clock signal.

In some embodiments, the first DAC settling portion of the low phase of the clock signal is associated with a first settling time.

In some embodiments, the first settling time is associated with a time required to settle a first voltage on a first side of the first switch with a second voltage on a second side of the first switch.

In some embodiments, the first settling time is less than one-half of the low phase of the clock signal.

In some embodiments, the method further comprises generating an inverted and delayed clock signal by transmitting the clock signal through buffer circuitry configured to invert and delay the clock signal by a buffer circuit delay.

In some embodiments, the method further comprises generating a first switch close signal based on a logic OR operation of the clock signal and the inverted and delayed clock signal, wherein the first switch is closed based on the first switch close signal.

In some embodiments, the method further comprises inverting the first switch close signal to generate an inverse switch close signal, wherein the first switch is closed based on the first switch close signal and the inverse switch close signal.

A continuous time sigma-delta analog-to-digital converter is also provided. The continuous time sigma-delta analog-to-digital converter comprising difference amplifier circuitry, a continuous time loop filter, quantization circuitry, and a dual digital-to-analog converter. The difference amplifier circuitry configured to receive an analog input signal and a feedback analog signal, and generate an analog difference signal between the analog input signal and the feedback analog signal. The continuous time loop filter configured to receive the analog difference signal and generate a filtered analog difference signal. The quantization circuitry configured to receive the filtered analog difference signal and generate a digital output based on a comparison of the filtered analog difference signal to a reference voltage. The dual digital-to-analog converter configured to generate the feedback analog signal based on the digital output, the dual digital-to-analog converter comprising a clock signal, a first digital-to-analog converter, a second digital-to-analog converter, and a DAC switching control circuit. The clock signal comprising a high phase and a low phase. The first digital-to-analog converter, comprising a first switch, wherein the first digital-to-analog converter is configured to generate a first analog output portion of the feedback analog signal based on the digital output during the high phase of the clock signal. The second digital-to-analog converter comprising a second switch, wherein the second digital-to-analog converter is configured to generate a second analog output portion of the feedback analog signal based on the digital output during the low phase of the clock signal. The DAC switching control circuit configured to close the first switch during a first DAC settling portion of the low phase of the clock signal and open the first switch during a first DAC open portion of the low phase of the clock signal.

In some embodiments, the DAC switching control circuit is further configured to close the second switch during a second DAC settling portion of the high phase of the clock signal and open the second switch during a second DAC open portion of the high phase of the clock signal.

### BRIEF DESCRIPTION OF THE DRAWINGS

Reference will now be made to the accompanying drawings. The components illustrated in the figures may or may not be present in certain embodiments described herein. Some embodiments may include fewer (or more) components than those shown in the figures in accordance with an example embodiment of the present disclosure.

FIG. 1 illustrates an example block diagram of an example dual digital-to-analog converter.

FIG. 2 illustrates an example signal diagram for an example dual return-to-zero digital-to-analog converter.

FIG. 3A-FIG. 3B illustrate an example circuit diagram of an example dual return-to-zero digital-to-analog converter and associated signal generation circuitry.

FIG. 4 illustrates an example block diagram of an example DAC switching control circuit configured to operate in conjunction with a dual digital-to-analog converter in accordance with an example embodiment of the present disclosure.

FIG. 5 illustrates an example circuit diagram of example short switches in accordance with an example embodiment of the present disclosure.

FIG. 6 illustrates an example circuit diagram of an example DAC switching control circuit in accordance with an example embodiment of the present disclosure.

FIG. 7 depicts an example signal diagram depicting a first switch close signal and an inverse switch close signal in accordance with an example embodiment of the present disclosure.

FIG. 8 depicts an example signal diagram depicting first switch and second switch close signals in accordance with an example embodiment of the present disclosure.

FIG. 9 depicts a block diagram of an example continuous time sigma-delta analog-to-digital converter including a dual digital-to-analog converter in accordance with an example embodiment of the present disclosure.

FIG. 10 illustrates an example circuit diagram of a portion of a continuous time sigma-delta analog-to-digital converter including a dual digital-to-analog converter in accordance with an example embodiment of the present disclosure.

FIG. 11 illustrates a flow chart depicting an example process for generating an analog output signal based on a digital input signal in accordance with an example embodiment of the present disclosure.

### DETAILED DESCRIPTION

Example embodiments will be described more fully hereinafter with reference to the accompanying drawings, in which some, but not all embodiments of the inventions of the disclosure are shown. Indeed, embodiments of the disclosure may be embodied in many different forms and should not be construed as limited to the embodiments set forth herein; rather, these embodiments are provided so that this disclosure will satisfy applicable legal requirements. Like numbers refer to like elements throughout.

Various example embodiments address technical problems associated with generating an analog output signal at a dual digital-to-analog converter. As understood by those of skill in the field to which the present disclosure pertains, there are numerous example systems which may benefit from efficiently generating an analog output signal based on a digital input signal from a dual digital-to-analog converter.

For example, various electronic systems require conversion between digital and analog signals. Many communication systems utilize both digital signals and analog signals in various aspects of operation of the electronic systems. Thus, electronic signals are continuously converted between analog and digital domains. A digital-to-analog converter (DAC) is an electronic device that converts digital signals into analog signals. Digital-to-analog converters may be designed for various types of operation, depending on the application.

For example, a digital-to-analog converter may be designed as a non-return-to-zero digital-to-analog converter. A non-return-to-zero digital-to-analog converter is a type of digital-to-analog converter that holds its analog output constant between updates. Thus, the analog output signal of the non-return-to-zero digital-to-analog converter remains constant at the analog value corresponding to the most recent digital input until the next update or sample. Non-return-to-zero digital-to-analog converters may introduce non-linearity into a system based on inter-symbol interference. Inter-symbol interference may occur in a non-return-to-zero digital-to-analog converter due to rise-fall asymmetry. Rise-fall asymmetry describes the discrepancy in rise and fall times for a non-return-to-zero digital-to-analog converter. For example, a rising transition at the output of the non-return-to-zero digital-to-analog converter may be different than the falling transition at the output of the non-return-to-zero digital-to-analog converter. Asymmetric transitions may introduce errors in an electrical component relying on the non-return-to-zero digital-to-analog converter. Because of the asymmetric transitions, the errors in the generated analog output are dependent on the sequence of inputs. Thus, a non-return-to-zero digital-to-analog converter may introduce non-linearity into an electronic system.

Due to the asymmetric transitions at the analog output of a non-return-to-zero digital-to-analog converter, many systems utilize a return-to-zero digital-to-analog converter to generate an analog output. A return-to-zero digital-to-analog converter generates an analog output during a first portion of a clock cycle. The return-to-zero digital-to-analog converter then returns to zero during a second portion of the clock cycle. Thus, there is a rising and falling transition in every cycle. As such, the return-to-zero digital-to-analog converter makes the error due to asymmetric transitions independent of input sequence. However, since the analog output is only asserted for a portion of the clock cycle, the amplitude of the analog output must be increased (e.g., doubled). The increased amplitude may have adverse effects on op-amp linearity and clock jitter sensitivity in an electronic system (e.g., continuous time sigma-delta ADC).

Dual return-to-zero digital-to-analog converters are used to overcome some of these drawbacks.

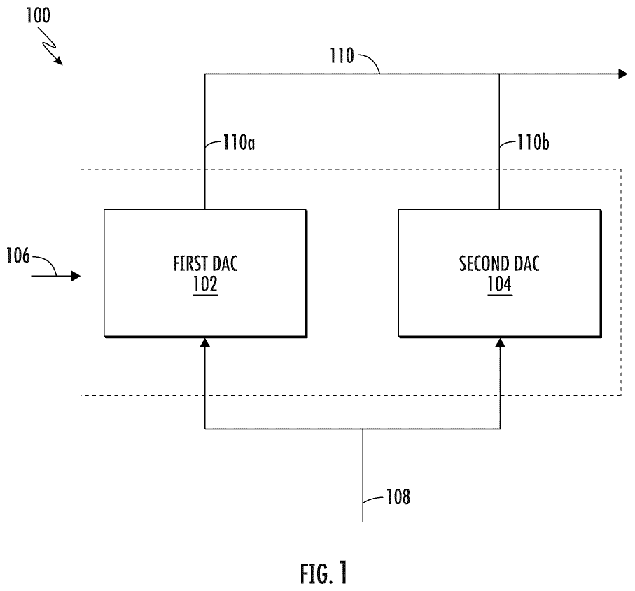

Referring now to FIG. 1, an example dual digital-to-analog converter 100 is depicted. As depicted in FIG. 1, the example dual digital-to-analog converter 100 includes a first digital-to-analog converter 102 and a second digital-to-analog converter 104. The first digital-to-analog converter 102 and the second digital-to-analog converter 104 are configured to receive a digital signal 108 and in coordination generate an analog output signal 110. The first digital-to-analog converter 102 generating a first analog output portion 110a during a first phase (e.g., high phase) of a clock signal 106, and the second digital-to-analog converter 104 generating a second analog output portion 110b during a second phase (e.g., low phase).

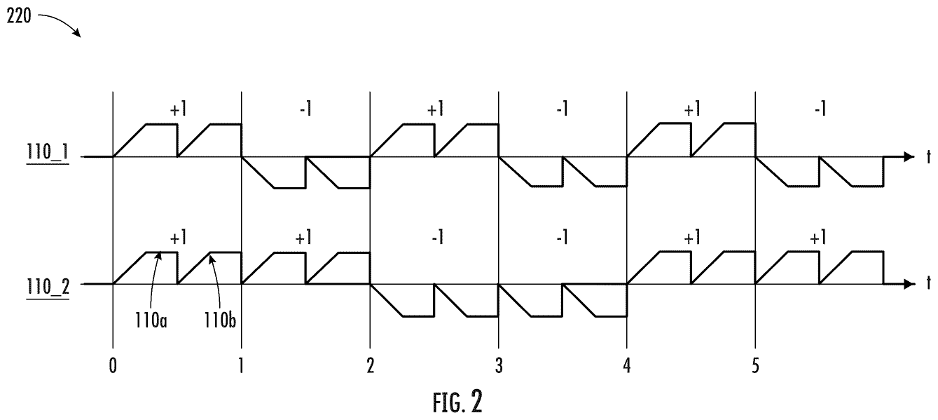

In a dual digital-to-analog converter 100, the selection of the digital-to-analog converter (e.g., first digital-to-analog converter 102 or second digital-to-analog converter 104) to generate the analog output signal 110 is determined based on the clock signal 106. For example, the clock signal 106 may oscillate between a high phase and a low phase. In some embodiments, during the high phase of the clock signal 106, the first digital-to-analog converter 102 is enabled. The first digital-to-analog converter 102 generates the first analog output portion 110a during the high phase of the clock signal 106. During the low phase of the clock signal 106, the second digital-to-analog converter 104 may be enabled. The second digital-to-analog converter 104 generates the second analog output portion 110b during the low phase of the clock signal 106. An example analog output signal 110 generated by a dual digital-to-analog converter 100 is shown in FIG. 2.

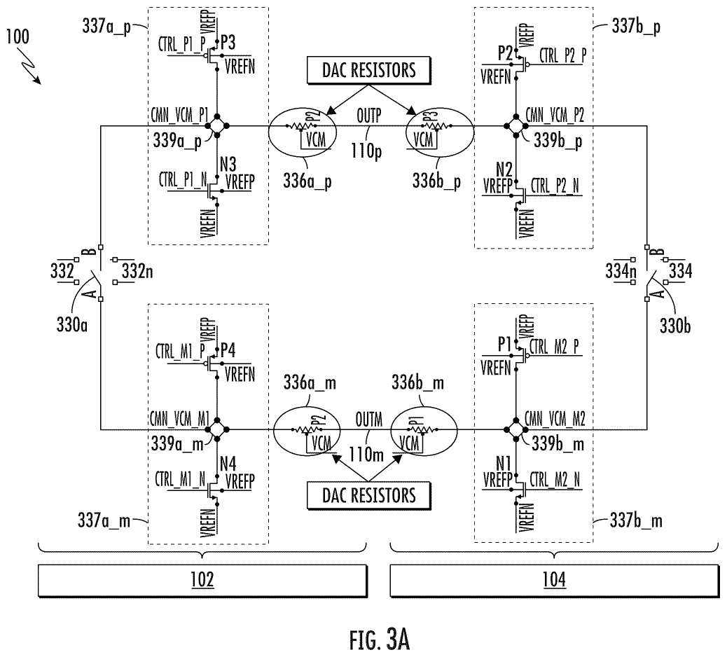

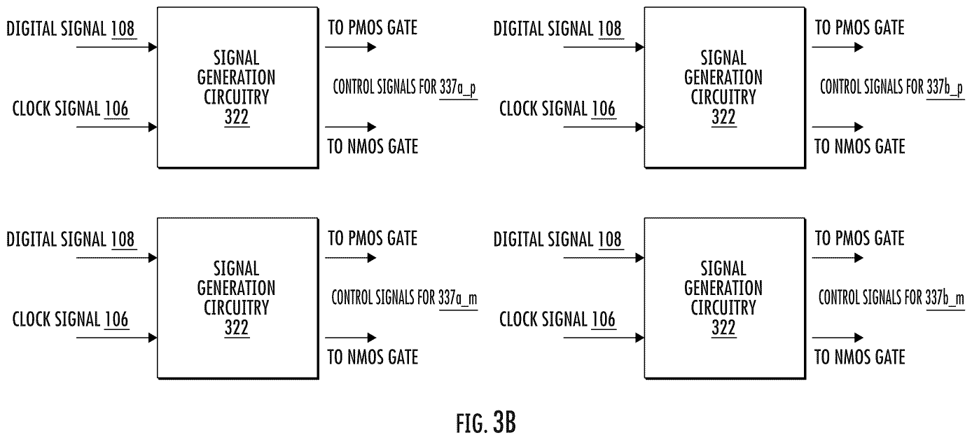

The first digital to analog converter 102 and the second digital to analog converter 104 are alternately enabled during operation based on the value of the digital signal 108 and associated control circuitry (as depicted in FIG. 3A). For example, the first digital-to-analog converter 102 is enabled to generate a first analog output portion 110a of the analog output signal 110 and the second digital-to-analog converter 104 is enabled to generate a second analog output portion 110b of the analog output signal 110. Each digital to analog converter 102, 104 also includes a shorting switch to return the analog output portion 110a/110b to zero when not enabled.

Thus, in an instance in which the first digital-to-analog converter 102 is enabled, the second digital-to-analog converter 104 is disabled. Further, in an instance in which the first digital-to-analog converter 102 is disabled, the second digital-to-analog converter 104, is enabled. For this reason, in some embodiments, the first shorting switch is controlled based on the rising edge and/or high phase of the clock signal 106, while the second shorting switch is controlled based on the falling edge and/or low phase of the clock signal 106. An example dual digital-to-analog converter 100 comprising a first shorting switch and a second shorting switch is described in relation to FIG. 3A.

Referring now to FIG. 2, an example signal diagram 220 depicting two example analog output signals 110_1, 110_2 is provided. As depicted in FIG. 2, the example analog output signal 110_1, 110_2 comprises a first analog output portion 110a generated by a first digital-to-analog converter 102 during a high phase of the clock signal (e.g., clock signal 106), and a second analog output portion 110b generated by a second digital-to-analog converter 104 during a low phase of the clock signal 106. By returning to zero following each transition of the analog output signal 110_1, 110_2, non-linearities due to asymmetric transitions may be overcome. In addition, by generating a first analog output portion 110a during the high phase of the clock signal 106 and a second analog output portion 110b during the low phase of the clock signal 106, the amplitude of the analog output signal 1101, 110_2 may be reduced.

However, additional noise may be introduced into the analog output signal 110 generated by a dual digital-to-analog converter (e.g., dual digital-to-analog converter 100) due to the switching mechanism utilized to switch between the first digital-to-analog converter (e.g., first digital-to-analog converter 102) and the second digital-to-analog converter (e.g., digital-to-analog converter 104).

Referring now to FIG. 3A and FIG. 3B, an example circuit diagram of an example dual digital-to-analog converter 100 is provided. As depicted in FIG. 3A, the example dual digital-to-analog converter 100 includes a first digital-to-analog converter 102 and a second digital-to-analog converter 104. The dual digital-to-analog converter 100 is configured to generate an analog output signal (e.g., analog output signal 110) at the output nodes 110p, 110m based on the various outputs of the signal generation circuitry 322 as depicted in FIG. 3B.

As depicted in FIG. 3B, a pair of control signals (one for the PMOS gate and one for the NMOS gate) are generated for each of the control systems 337a_p, 337b_p, 337a_m, 337b_m of the dual digital-to-analog converter 100 based on the digital signal 108 and the clock signal 106. The control signals generated by the signal generation circuitry 322 control the corresponding digital-to-analog converter 102, 104 based on the digital signal 108 when the corresponding digital-to-analog converter 102, 104 is in an active state.

As depicted in FIG. 3A, the first digital-to-analog converter 102 includes a first portion configured to provide the analog output signal at the output node 110p and a second portion configured to provide the analog output signal at the output node 110m. The first portion comprises a DAC resistor 336a_p electrically connected between the output node 110p and the net point 339a_p. The net point 339a_p is further electrically connected to a first terminal of the shorting switch 330a. In addition, the second portion comprises a DAC resistor 336a_m electrically connected between the output node 110m and the net point 339a_m. The net point 339a_m is further electrically connected to a second terminal of the shorting switch 330a. The shorting switch 330a is controlled by the first switch close signal 332 and the inverse first switch close signal 332n.

In an instance in which the shorting switch 330a is open, the first voltage at the net point 339a_p is defined by the control system 337a_p. The control system 337a_p sets the first voltage of the net point 339a_p based on the control signals for 337a_p generated by the signal generation circuitry 322 as depicted in FIG. 3B. Further, the second voltage at the net point 339a_m is defined by the control system 337a_m. The control system 337a_m sets the second voltage of the net point 339a_m based on the control signals for 337a_m generated by the signal generation circuitry 322 as depicted in FIG. 3B. Thus, the first voltage at the net point 339a_p and the second voltage at the net point 339a_m are at two different extremes of reference voltage of the DAC (e.g., VREFP and VREFN) in an instance in which the shorting switch 330a is open. During the time at which the shorting switch 330a is open, the first digital-to-analog converter 102 is generating the first analog output portion of the analog output signal at the output nodes 110p, 110m.

In an instance in which the shorting switch 330a is closed, the net point 339a_p and the net point 339a_m are electrically connected. Thus, the voltage difference between the net point 339a_p and net point 339a_m is neutralized after a settling time. A settling time in the context of this disclosure is any time required to neutralize the voltage difference across the open shorting switch 330a, from the time the shorting switch 330a is closed. The shorting time may be dependent upon the shorting switch resistance and/or various parasitic capacitances within the first digital-to-analog converter 102. Further, in an instance in which the shorting switch 330a is closed, the second digital-to-analog converter 104 is generating the second analog output portion of the analog output signal at the output nodes 110p, 110m.

Similar to the first digital-to-analog converter 102, as depicted in FIG. 3A, the second digital-to-analog converter 104 includes a first portion configured to provide the analog output signal at the output node 110p and a second portion configured to provide the analog output signal at the output node 110m. The first portion comprises a DAC resistor 336b_p electrically connected between the output node 110p and the net point 339b_p. The net point 339b_p is further electrically connected to a first terminal of the shorting switch 330b. In addition, the second portion comprises a DAC resistor 336b_m electrically connected between the output node 110m and the net point 339b_m. The net point 339b_m is further electrically connected to a second terminal of the shorting switch 330b. The shorting switch 330b is controlled by the second switch close signal 334 and the inverse second switch close signal 334n.

In an instance in which the shorting switch 330b is open, the first voltage at the net point 339b_p is defined by the control system 337b_p. The control system 337b_p sets the first voltage of the net point 339b_p based on the control signals for 337b_p generated by the signal generation circuitry 322 as depicted in FIG. 3B. Further, the second voltage at the net point 339b_m is defined by the control system 337b_m. The control system 337b_m sets the second voltage of the net point 339b_m based on the control signals for 337b_m generated by the signal generation circuitry 322 as depicted in FIG. 3B. Thus, the first voltage at the net point 339b_p and the second voltage at the net point 339b_m are at two different extremes of reference voltage of the DAC (e.g., VREFP and VREFN) in an instance in which the shorting switch 330b is open. During the time at which the shorting switch 330b is open, the second digital-to-analog converter 104 is generating the second analog output portion of the analog output signal at the output nodes 110p, 110m.

In an instance in which the shorting switch 330b is closed, the net point 339b_p and the net point 339b_m are electrically connected. Thus, the voltage difference between the net point 339b_p and net point 339b_m is neutralized after a settling time. A settling time in the context of this disclosure is any time required to neutralize the voltage difference across the open shorting switch 330b, from the time the shorting switch 330b is closed. The shorting time may be dependent upon the shorting switch resistance, and/or various parasitic capacitances within the second digital-to-analog converter 104. Further, in an instance in which the shorting switch 330b is closed, the first digital-to-analog converter 102 is generating the first analog output portion of the analog output signal at the output nodes 110p, 110m.

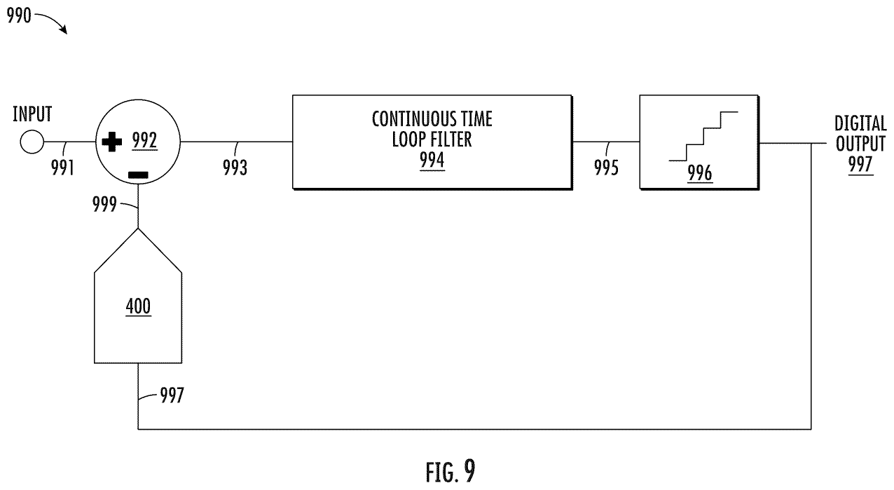

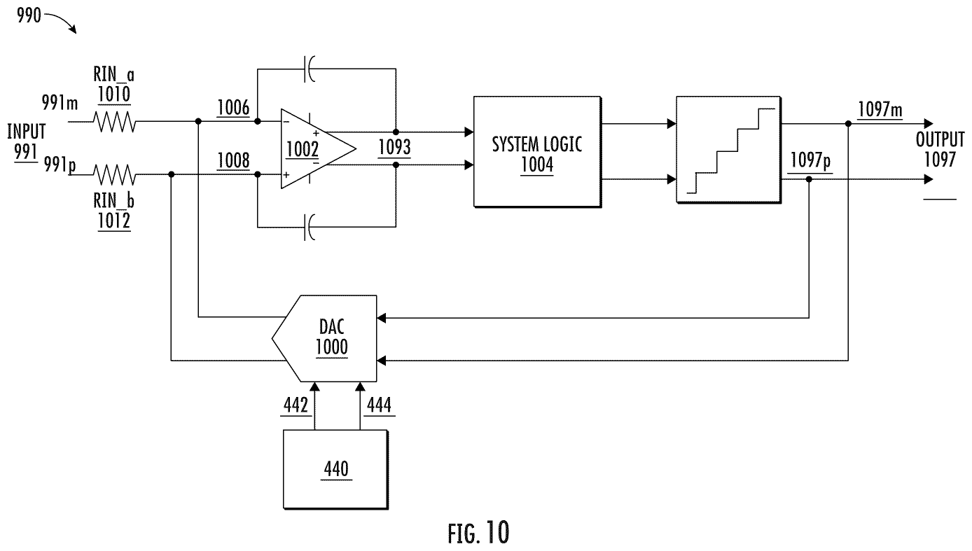

In an instance in which a digital-to-analog converter (e.g., first digital-to-analog converter 102, second digital-to-analog converter 104) of the dual digital-to-analog converter 100 is disabled, DAC resistors (e.g., DAC resistors 336a_p, 336b_p, 336a_m, 336b m) of the disabled digital-to-analog converter continue to inject thermal noise, into the system utilizing the dual digital-to-analog converter 100. Due to this additional resistor, other noise sources in the system (e.g., op-amp noise in connected electrical components) see an increased gain when referred to the output. The additional noise due to resistor as well as due to other noise sources, for example an op-amp, may have adverse effects on the performance of the system. For example, as depicted in FIG. 9-FIG. 10, the additional current injected into a continuous time sigma-delta analog-to-digital (ADC) converter may hamper the output signal-to-noise ratio of the output signal. Thus, there is a need for a dual digital-to-analog converter 100 configured to generate an analog output signal while limiting the introduction of noise into the system.

The various example embodiments described herein utilize various techniques to limit the introduction of noise into an analog output signal of a dual digital-to-analog converter. For example, in some embodiments, the dual digital-to-analog converter may include a DAC switching control circuit to control shorting switches at a first digital-to-analog converter and a second digital-to-analog converter within the dual digital-to-analog converter. The DAC switching control circuit may be configured to close the shorting switch of the disabled digital-to-analog converter for a settling portion of the digital-to-analog converter. The settling portion may be based on the settling time of the disabled digital-to-analog converter. Once the disabled digital-to-analog converter has neutralized the first and second voltages across the shorting switch of the disabled digital-to-analog converter, the shorting switch of the disabled digital-to-analog converter may be opened. By opening the shorting circuit of the disabled digital-to-analog converter after a settling time, the disabled digital-to-analog converter may no longer inject unwanted noise through the resistor into the system, as well as due to increased gain seen by other noise sources such as op-amp at the analog output signal of the dual digital-to-analog converter.

As a result of the herein described example embodiments and in some examples, the noise introduced by a dual digital-to-analog converter may be greatly reduced. In addition, the performance of an electronic system (e.g., continuous time sigma-delta ADC) utilizing the dual digital-to-analog converter may be greatly improved.

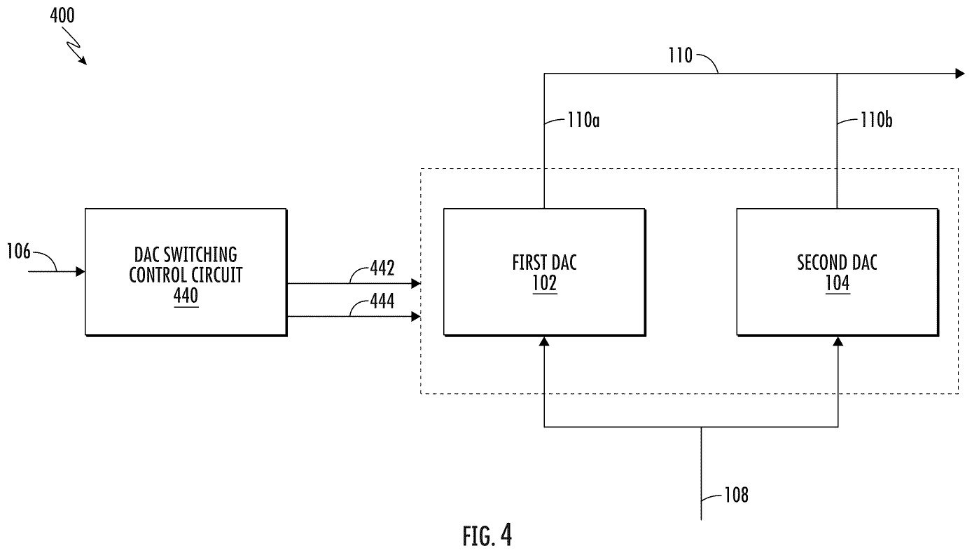

Referring now to FIG. 4, an example dual digital-to-analog converter 400 comprising a DAC switching control circuit 440 in accordance with the present disclosure is depicted. As depicted in FIG. 4, the dual digital-to-analog converter 400 includes a first digital-to-analog converter 102 and a second digital-to-analog converter 104. The first digital-to-analog converter 102 and the second digital-to-analog converter 104 are configured to receive a digital signal 108 and generate an analog output signal 110 in coordination. The first digital-to-analog converter 102 generating a first analog output portion 110a during a first phase (e.g., high phase) of a clock signal 106, and the second digital-to-analog converter 104 generating a second analog output portion 110b during a second phase (e.g., low phase). As further depicted in FIG. 4, the dual digital-to-analog converter 400 includes a DAC switching control circuit 440. The DAC switching control circuit 440 is configured to receive the clock signal 106 and generate a first switch triggering signal 442 and a second switch triggering signal 444.

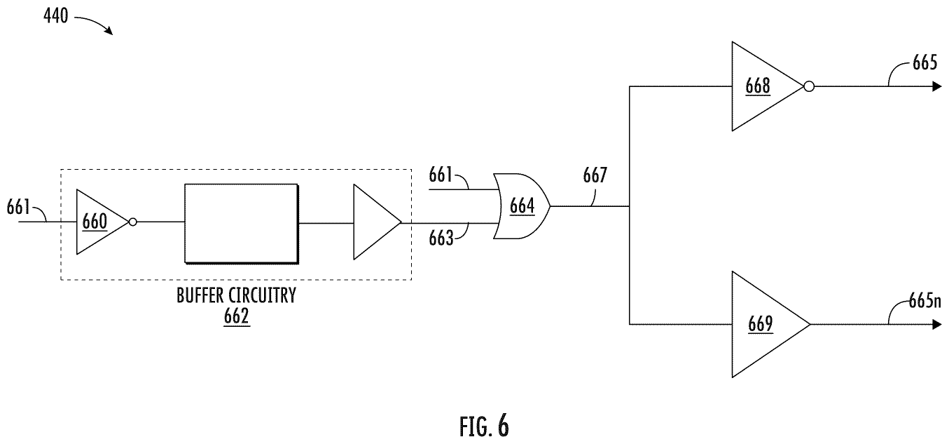

As depicted in FIG. 4, the dual digital-to-analog converter 400 includes DAC switching control circuit 440. A DAC switching control circuit 440 comprises any circuitry including, but not limited to active electronic components, configured to receive the clock signal 106 and generate a first switch triggering signal 442 and a second switch triggering signal 444. An example embodiment of a DAC switching control circuit 440 is further described in relation to FIG. 6.

As described in relation to FIG. 3A, each digital-to-analog converter (e.g., first digital-to-analog converter 102, second digital-to-analog converter 104) is associated with a shorting switch (e.g., shorting switch 330a, shorting switch 330b as described in relation to FIG. 3A). The first switch triggering signal 442 is any electronic signal or plurality of electronic signals configured to close a first switch (e.g., shorting switch 330a) associated with the first digital-to-analog converter 102 for a portion (e.g., settling portion) of the associated phase of the clock signal (e.g., low phase).

For example, in an embodiment in which the first digital-to-analog converter 102 is enabled during the high phase of the clock signal 106, the first switch triggering signal 442 is configured to open the first switch for the duration of the high phase of the clock signal 106. In such an embodiment, during the low phase of the clock signal 106, the first digital-to-analog converter 102 is disabled. The first digital-to-analog converter 102 is disabled through the signal generation circuitry (e.g., signal generation circuitry 322 of FIG. 3B) associated with the first digital-to-analog converter 102 (e.g., control signals for control system 337a_p and control system 337a_m). At the same time the associated shorting switch is closed. However, once the voltage generated by the control system (e.g., control system 337a_p) of the first portion of the digital-to-analog converter is shorted with the voltage generated by the control system (e.g., control system 337a_m) of the second portion of the digital-to-analog converter, the shorting switch no longer needs to be closed. In fact, keeping the shorting switch closed once the voltage at the digital-to-analog converter has settled increases noise injected, into the system.

The time required to neutralize and/or settle the voltage generated by the control system (e.g., control system 337a_p) of the first portion of the digital-to-analog converter with the voltage generated by the control system (e.g., control system 337a_m) of the second portion of the digital-to-analog converter is referred to herein as settling time.

The first switch triggering signal 442, and/or one or more signals generated based on the first switch triggering signal 442, are configured to close the first shorting switch associated with the first digital-to-analog converter 102 for a first settling time associated with the first digital-to-analog converter 102 once the clock phase changes (e.g., at the falling edge of clock signal 106). The portion of the clock signal 106 for which the first shorting switch is closed is referred to as the first DAC settling portion of the clock signal 106. In some embodiments, the first DAC settling portion may be determined based on the settling time associated with the first digital-to-analog converter 102. In some embodiments, the settling time and/or the first DAC settling portion may be represented in terms of a portion of the clock phase (e.g., low phase or high phase). For example, in some embodiments, the settling time and/or associated first DAC settling portion may be less than one-half of the low phase of the clock signal; more preferably, less than one-third of the low phase of the clock signal; most preferably, less than one-quarter of the low phase of the clock signal.

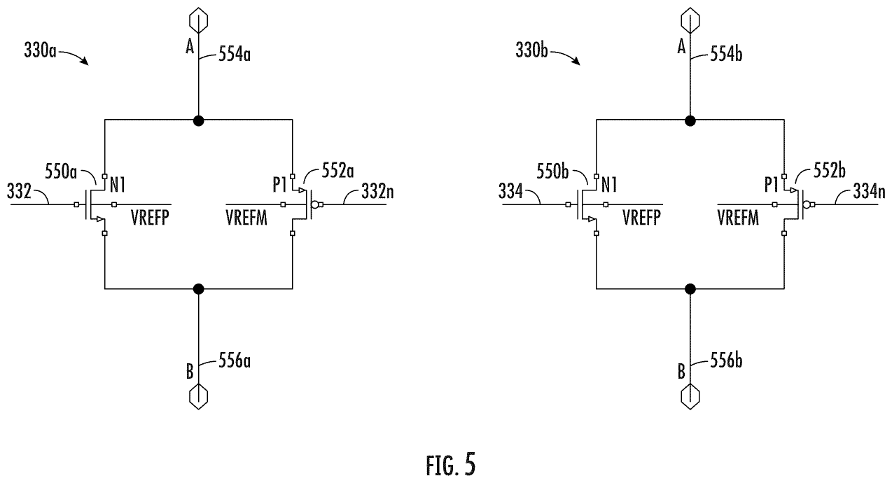

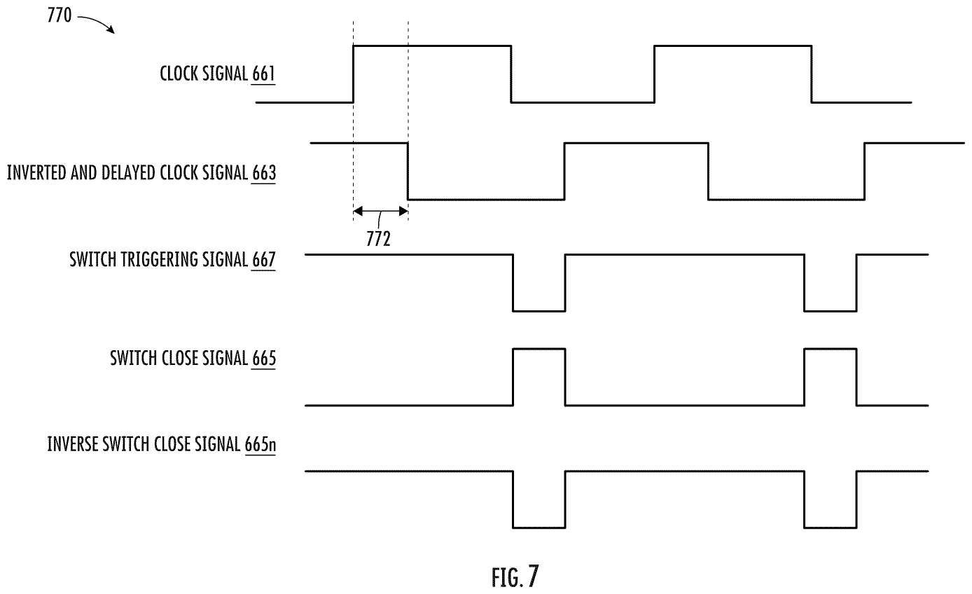

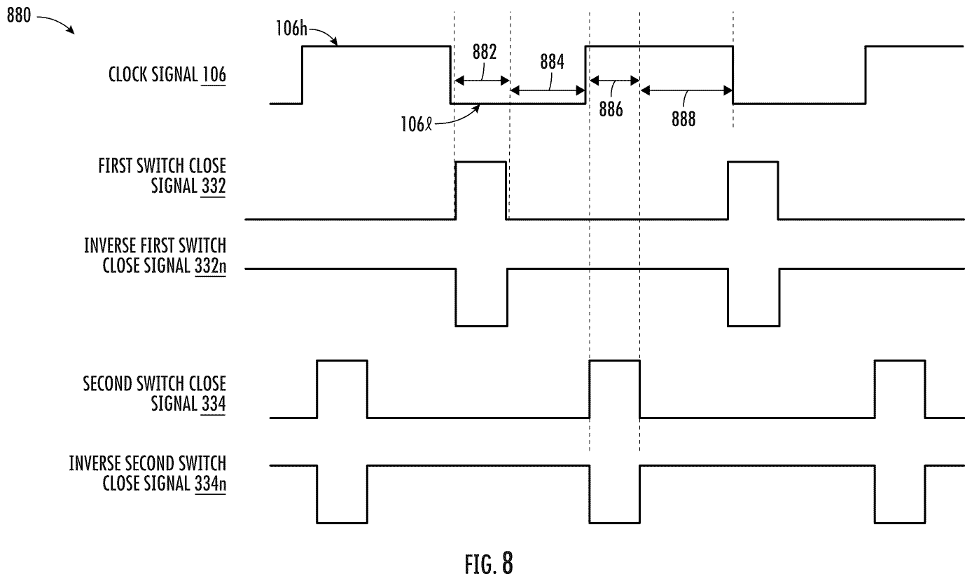

The second switch triggering signal 444, and/or one or more signals generated based on the second switch triggering signal 444, are configured to close the second shorting switch of the second digital-to-analog converter 104 for a first settling time associated with the second digital-to-analog converter 104 once the clock phase changes (e.g., at the rising edge of clock signal 106). The portion of the clock signal 106 for which the second shorting switch is closed is referred to as the second DAC settling portion of the clock signal 106. In some embodiments, the second DAC settling portion may be determined based on the settling time associated with the second digital-to-analog converter 104. In some embodiments, the settling time and/or the second DAC settling portion may be represented in terms of a portion of the clock phase (e.g., low phase or high phase). For example, in some embodiments, the settling time and associated second DAC settling portion may be less than one-half of the high phase of the clock signal; more preferably, less than one-third of the high phase of the clock signal; most preferably, less than one-quarter of the high phase of the clock signal. Example first and second shorting switches are described further in relation to FIG. 5. Example switch triggering signals (e.g., first switch triggering signal 442, second switch triggering signal 444) are further described in relation to FIG. 7 and FIG. 8.

Referring now to FIG. 5, an example first shorting switch 330a and an example second shorting switch 330b are provided. Although not shown, a first shorting switch 330a is associated with a first digital-to-analog converter (e.g., first digital-to-analog converter 102), while the second shorting switch 330b is associated with a second digital-to-analog converter (e.g., second digital-to-analog converter 104).

As depicted in FIG. 5, the first shorting switch 330a comprises a first terminal 554a and a second terminal 556a. The first terminal 554a is electrically connected to a first portion of the first digital-to-analog converter, while the second terminal 556a is electrically connected to a second portion of the first digital-to-analog converter. Thus, in an instance in which the first shorting switch 330a is open, a first voltage may be generated at the first terminal 554a and a second voltage at the second terminal 556a. In an instance in which the first shorting switch 330a is closed, the first terminal 554a and the second terminal 556a are electrically connected and the first voltage and second voltage settle at a common voltage. The time required to settle at a common voltage once the first shorting switch 330a is closed is referred to as the settling time and the first DAC settling portion of the clock signal may be based on the settling time.

As further depicted in FIG. 5, the first shorting switch 330a comprises an NMOS transistor 550a and a PMOS transistor 552a electrically connected to the first terminal 554a and the second terminal 556a in parallel. The NMOS transistor 550a is configured to receive the first switch close signal 332 at a gate terminal. The PMOS transistor 552a is configured to receive the inverse first switch close signal 332n at a gate terminal. The inverse first switch close signal 332n is an inverted copy of the first switch close signal 332. Thus, as depicted in FIG. 5, in an instance in which the first switch close signal 332 is in a high voltage state and the inverse first switch close signal 332n is in a low voltage state, the first shorting switch 330a is closed. Conversely, in an instance in which the first switch close signal 332 is in a low voltage state and the inverse first switch close signal 332n is in a high voltage state, the first shorting switch 330a is open. The first switch close signal 332 and the inverse first switch close signal 332n are generated based on the first switch triggering signal 442. Thus, the first shorting switch 330a is open and closed based on the first switch triggering signal 442.

As depicted in FIG. 5, the second shorting switch 330b comprises a first terminal 554b and a second terminal 556b. The first terminal 554b is electrically connected to a first portion of the second digital-to-analog converter, while the second terminal 556b is electrically connected to a second portion of the second digital-to-analog converter. Thus, in an instance in which the second shorting switch 330b is open, a first voltage may be generated at the first terminal 554b and a second voltage at the second terminal 556b. In an instance in which the first shorting switch 330b is closed, the first terminal 554b and the second terminal 556b are electrically connected and the first voltage and second voltage settle at a common voltage. The time required to settle at a common voltage once the second shorting switch 330b is closed is referred to as the settling time and the second DAC settling portion of the clock signal may be based on the settling time.

As further depicted in FIG. 5, the second shorting switch 330b comprises an NMOS transistor 550b and a PMOS transistor 552b electrically connected to the first terminal 554b and the second terminal 556b in parallel. The NMOS transistor 550b is configured to receive the second switch close signal 334 at a gate terminal. The PMOS transistor 552b is configured to receive the inverse second switch close signal 334n at a gate terminal. The inverse second switch close signal 334n is an inverted copy of the second switch close signal 334. Thus, as depicted in FIG. 5, in an instance in which the second switch close signal 334 is in a high voltage state and the inverse second switch close signal 334n is in a low voltage state, the second shorting switch 330b is closed. Conversely, in an instance in which the second switch close signal 334 is in a low voltage state and the inverse second switch close signal 334n is in a high voltage state, the second shorting switch 330b is open. The second switch close signal 334 and the inverse second switch close signal 334n are generated based on the second switch triggering signal 444. Thus, the second shorting switch 330b is open and closed based on the second switch triggering signal 444.

Referring now to FIG. 6, an example embodiment of a DAC switching control circuit 440 is provided. As depicted in FIG. 6, the example DAC switching control circuit 440 is configured to receive a clock signal 661 and generate a switch close signal 665 and an inverse switch close signal 665n. The DAC switching control circuit 440 comprises buffer circuitry 662 associated with a buffer circuit delay configured to receive the clock signal 661 and, generate an inverted and delayed clock signal 663 delayed by the buffer circuit delay. The DAC switching control circuit 440 further includes an OR gate 664 configured to receive the inverted and delayed clock signal 663 and the clock signal 661 and generate a switch triggering signal 667. The DAC switching control circuit 440 further includes an inverter 668 configured to receive the switch triggering signal 667 and generate the switch close signal 665. The DAC switching control circuit 440 further includes a buffer 669 configured to receive the switch triggering signal 667 and generate the inverse switch close signal 665n in synchronization with the switch close signal 665.

The example DAC switching control circuit 440 depicted in FIG. 6 may be utilized to generate the switch close signal 665 and inverse switch close signal 665n for both a first shorting switch (e.g., first shorting switch 330a) associated with a first digital-to-analog converter (e.g., first digital-to-analog converter 102) and a second shorting switch (e.g., second shorting switch 330b) associated with a second digital-to-analog converter (e.g., second digital-to-analog converter 104). For example, in an instance in which the clock signal (e.g., clock signal 106) received at the dual digital-to-analog converter is transmitted to the DAC switching control circuit 440 as the clock signal 661, the generated switch close signal 665 is utilized as the first switch close signal (e.g., first switch close signal 332) and the generated inverse switch close signal 665n is utilized as the inverse first switch close signal (e.g., inverse first switch close signal 332n). Further, in an instance in which the inverse of the clock signal (e.g., clock signal 106) received at the dual digital-to-analog converter is transmitted to the DAC switching control circuit 440 as the clock signal 661, the generated switch close signal 665 is utilized as the second switch close signal (e.g., second switch close signal 334) and the generated inverse switch close signal 665n is utilized as the inverse second switch close signal (e.g., inverse first switch close signal 334n).

In some embodiments, the DAC switching control circuit 440 depicted in FIG. 6 may be duplicated. In such an embodiment, the first DAC switching control circuit 440 may receive the clock signal 106 (e.g., clock signal 661), generate the first switch triggering signal 442 (e.g., switch triggering signal 667), and generate the first switch close signal 332 (e.g., switch close signal 665) and the inverse first switch close signal 332n (e.g., inverse switch close signal 665n) based on the first switch triggering signal 442. Further, the second DAC switching control circuit 440 may receive the inverse of the clock signal 106 (e.g., clock signal 661), generate the second switch triggering signal 444 (e.g., switch triggering signal 667), and generate the second switch close signal 334 (e.g., switch close signal 665) and the inverse second switch close signal 334n (e.g., inverse switch close signal 665n) based on the second switch triggering signal 444.

As depicted in FIG. 6, the DAC switching control circuit 440 includes buffer circuitry 662. The buffer circuitry 662 comprises any electrical components, including but not limited to active electrical components, configured to delay the clock signal 661 by a time period (e.g., buffer circuit delay) associated with a settling time of an associated digital-to-analog converter. In some embodiments, the buffer circuitry 662 may include a series of inverters 660 configured to delay the clock signal 661 by the buffer circuit delay. In an instance in which an odd number of inverters 660 are used in the buffer circuitry 662, the generated inverted and delayed clock signal 663 represents an inverted value of the clock signal 661 and delayed according to the buffer circuit delay based on the buffer circuitry 662.

The buffered circuit delay associated with the buffer circuitry 662 determines the duration of time for which the switch close signal 665 is asserted and the inverse switch close signal 665n is de-asserted. Thus, the buffer circuit delay associated with the buffer circuitry 662 determines the duration of time for which the shorting switch associated with a digital-to-analog converter configured to receive the switch close signal 665 is closed. In other words, the buffer circuit delay of the buffer circuitry 662 may be defined depending on the settling requirement of the DAC of the associated digital-to-analog converter.

In some embodiments, the buffer circuitry 662 may be configured to delay the clock signal 661 for a buffer circuit delay equal to the settling time of an associated digital-to-analog converter. In some embodiments, the buffer circuitry 662 may be configured to delay the clock signal 661 for a buffer circuit delay exceeding an average and/or maximum settling time associated with one or more digital-to-analog converters. For example, an average and/or max settling time of one or more digital-to-analog converters comprising similar electrical components to a digital-to-analog converter associated with the DAC switching control circuit 440.

Referring now to FIG. 7, an example signal diagram 770 depicting a switch close signal 665 and an inverse switch close signal 665n generated based on a clock signal 661 received at a DAC switching control circuit (e.g., DAC switching control circuit 440) is provided.

As depicted in FIG. 7, the inverted and delayed clock signal 663 is inverted and delayed in relation to the clock signal 661 by a buffer circuit delay 772. As described in relation to FIG. 6, the buffer circuit delay 772 may be associated with a delay introduced by the buffer circuitry 662 of the DAC switching control circuit 440.

As further depicted in FIG. 7, the switch triggering signal 667 is generated by performing a logical OR operation between the clock signal 661 and the inverted and delayed clock signal 663. As can be seen in the signal diagram 770 of FIG. 7, the switch triggering signal 667 is de-asserted for a period of time equal to the buffer circuit delay 772.

As further depicted in FIG. 7, the switch close signal 665 is the inverse of the switch triggering signal 667. The switch close signal 665 may be utilized as a switch close signal (e.g., first switch close signal 332, second switch close signal 334) of an associated digital-to-analog converter. The inverse switch close signal 665n is a logical inverse of the switch close signal 665. The inverse switch close signal 665n may be utilized as an inverse switch close signal (e.g., inverse first switch close signal 332n, inverse second switch close signal 334n) of an associated digital-to-analog converter. Although not depicted in FIG. 7, in some embodiments, the switch close signal 665 and the inverse switch close signal 665n may be delayed with respect to the switch triggering signal 667. For example, the switch close signal 665 may be passed through an inverter (e.g., inverter 668 as shown in FIG. 6) associated with a delay. The inverse switch close signal 665n may be passed through a delay buffer with equivalent delay such that the switch close signal 665 and the inverse switch close signal 665n are synchronized.

Referring now to FIG. 8, an example signal diagram 880 depicting an example first and second switch close signals relative to a clock signal 106 is provided.

As described in relation to FIG. 6, the DAC switching control circuit 440 may be utilized to determine a first switch close signal 332 and an inverse first switch close signal 332n utilizing the clock signal 106 as an input to the DAC switching control circuit 440. In addition, the DAC switching control circuit 440 may be utilized to determine a second switch close signal 334 and an inverse second switch close signal 334n utilizing the inverse clock signal 106 as the input to the DAC switching control circuit 440.

As depicted in FIG. 8, the clock signal 106 comprises a high phase 106h and a low phase 106f. In the example of FIG. 8, a first digital-to-analog converter (e.g., first digital-to-analog converter 102) is configured to be enabled during the high phase 106h of the clock signal 106. A second digital-to-analog converter (e.g., second digital-to-analog converter 104) is configured to be enabled during the low phase 106f.

The first switch close signal 332 and inverse first switch close signal 332n are configured to control a shorting switch (e.g., shorting switch 330a) associated with the first digital-to-analog converter. Thus, in an instance in which the first switch close signal 332 is low and the inverse first switch close signal 332n is high, the shorting switch is open. Conversely, in an instance in which the first switch close signal 332 is high and the inverse first switch close signal 332n is low, the shorting switch is closed.

As depicted in FIG. 8, the first switch close signal 332 and inverse first switch close signal 332n close the switch for a first DAC settling portion 882 of the low phase 106f of the clock signal 106. The duration of the first DAC settling portion 882 is based on a settling time of the first digital-to-analog converter and is defined based on a buffer circuit delay within the DAC switching control circuit 440. As further depicted in FIG. 8, the shorting switch associated with the first digital-to-analog converter is open during a first DAC open portion 884 of the low phase 106f of the clock signal 106. Because unwanted noise may be injected into the system while the shorting switch associated with the disabled first digital-to-analog converter is closed, by limiting the amount of time at which the shorting switch associated with the first digital-to-analog converter is closed, the amount of noise introduced into the system may be reduced.

The second switch close signal 334 and inverse second switch close signal 334n are configured to control a shorting switch (e.g., shorting switch 330b) associated with the second digital-to-analog converter. Thus, in an instance in which the second switch close signal 334 is low and the inverse second switch close signal 334n is high, the shorting switch is open. Conversely, in an instance in which the second switch close signal 334 is high and the inverse second switch close signal 334n is low, the shorting switch is closed.

As depicted in FIG. 8, the second switch close signal 334 and inverse second switch close signal 334n close the switch for a second DAC settling portion 886 of the high phase 106h of the clock signal 106. The duration of the second DAC settling portion 886 is based on a settling time of the second digital-to-analog converter and is defined based on a buffer circuit delay within the DAC switching control circuit 440. As further depicted in FIG. 8, the shorting switch associated with the second digital-to-analog converter is open during a second DAC open portion 888 of the high phase 106h of the clock signal 106. Because unwanted noise may be injected into the system while the shorting switch associated with the disabled second digital-to-analog converter is closed, by limiting the amount of time at which the shorting switch associated with the second digital-to-analog converter is closed, the amount of noise introduced into the system may be reduced.

Referring now to FIG. 9, an example continuous time sigma-delta ADC 990 is provided. A continuous time sigma-delta ADC 990 is a type of data converter that receives an analog input signal 991 and generates a digital output signal 997 using oversampling and noise-shaping techniques. The continuous time sigma-delta ADC 990 utilizes a feedback loop including a dual digital-to-analog converter 400 to ensure stability and minimize noise. A continuous time sigma-delta ADC 990 may be utilized to generate digital output signals 997 in various applications, including in (not technically required) circuitry associated with communication systems, and radar systems.

As depicted in FIG. 9, the continuous time sigma-delta ADC 990 includes difference amplifier circuitry 992 configured to receive the analog input signal 991 and a feedback analog signal 999 and generate an analog difference signal 993. The analog input signal 991 comprises any continuous time analog input signal. The analog difference signal 993 represents the error between the analog input signal 991 and the generated digital output signal 997. The analog difference signal 993 may be used to reduce the noise in the digital output signal 997 and ensure the digital output signal 997 tracks the analog input signal 991 accurately.

As further depicted in FIG. 9, the continuous time sigma-delta ADC 990 includes a continuous time loop filter 994 configured to receive the analog difference signal 993 and generate a filtered analog difference signal 995. The continuous time loop filter 994 utilizes various filtering techniques to reduce noise and interference in the generated digital output signal 997, integrate the analog difference signal 993, and stabilize the feedback loop. In some embodiments, the continuous time loop filter 994 may include an operational amplifier, for example, an operational amplifier (e.g., operational amplifier 1002) as depicted in FIG. 10.

As further depicted in FIG. 9, the continuous time sigma-delta ADC 990 includes quantization circuitry 996 configured to receive the filtered analog difference signal 995 and generate a digital output signal 997. The quantization circuitry 996 utilizes various techniques to convert the filtered analog difference signal 995 into a discrete, digital representation of the analog input signal 991. The quantization circuitry 996 samples the analog input and converts it into the form of a 1-bit or multi-bit digital representation.

As further depicted in FIG. 9, the continuous time sigma-delta ADC 990 includes a dual digital-to-analog converter 400 comprising a DAC switching control circuit (e.g., DAC switching control circuit 440). The dual digital-to-analog converter 400 receives the digital output signal 997 and converts it back into a feedback analog signal 999 for comparison with the analog input signal 991. The dual digital-to-analog converter 400 ensures the digital output signal 997 closely tracks the continuous analog input signal 991. As described herein, by limiting the time a shorting switch is closed, the dual digital-to-analog converter 400 reduces the amount of noise introduced into the digital output signal 997 compared to traditional dual digital-to-analog converters 400.

Referring now to FIG. 10, an example, dual digital-to-analog converter 1000 configured to interface with an operational amplifier 1002 of a continuous time sigma-delta ADC (e.g., continuous time sigma-delta ADC 990) is depicted.

As depicted in FIG. 10, the analog input signal (e.g., analog input signal 991) is transmitted at the first analog input 991m and the second analog input 991p. A first input resistor 1010 is electrically connected between the first analog input 991m and a net point 1006. Similarly, a second input resistor 1012 is electrically connected between the second analog input 991p and a net point 1008.

The net point 1006 is further electrically connected to an inverting input (−) of an operational amplifier 1002. The net point 1008 is further electrically connected to a non-inverting input (+) of the operational amplifier 1002. The analog difference signal 1093 (e.g., analog difference signal 993) generated by the operational amplifier 1002 is transmitted to various system logic 1004 of the rest of the system. For example, a continuous time loop filter and quantization circuitry as shown in FIG. 9. The digital signal output 1097 (e.g., digital signal output 997) is generated at the first digital signal output 1097m and the second digital signal output 1097p.

As further depicted in FIG. 10, the first digital signal output 1097m is electrically connected to a first enabled DAC resistor and a first disabled DAC resistor (e.g., first enabled DAC resistor 336b_m, first disabled DAC resistor 336a_m as depicted in FIG. 3A) electrically connected in series between the first digital signal output 1097m and a shorting switch (e.g., first shorting switch 330a). In addition, the second digital signal output 1097p is electrically connected to a second enabled DAC resistor and a second disabled DAC resistor (e.g., second enabled DAC resistor 336b_p and second disabled DAC resistor 336a_p as depicted in FIG. 3A) electrically connected in series between the second digital signal output 1097p and the shorting switch.

As further depicted in FIG. 10, the shorting switch is controlled by a first switch triggering signal 442 and a second switch triggering signal 444 generated by a DAC switching control circuit 440. The various resistors of the example dual digital-to-analog converter 1000 may inject unwanted current and thus noise into the inputs of the operational amplifier 1002 and thus into the system. For example, at the non-inverting input (−) of the operational amplifier 1002, the first input resistor 1010, the first enabled DAC resistor, and the first disabled DAC resistor may all contribute to noise while the shorting switch is closed. However, when the shorting switch is open, there is no noise injected into the input of the operational amplifier 1002 from the first disabled DAC resistor. Thus, by reducing the amount of time the shorting switch is closed reduces the amount of noise injected into the system.

The DAC switching scheme implemented by the switching control circuit 440 and described herein provides reductions in noise (e.g., resistor noise and op-amp noise) introduced into an electronic system, for example, a continuous time sigma-delta ADC 990.

As an example, consider the noise introduced by the resistors (e.g., first input resistor 1010, the first enabled DAC resistor, and the first disabled DAC resistor) in the continuous time sigma-delta ADC 990 of FIG. 10. Assuming the noise contribution (Y) of each of these resistors is the same, the noise contribution of all the resistors when the switch is closed is equal to 3Y. As described herein, the switch is closed to enable the settling of a particular digital-to-analog converter within the dual digital-to-analog converter 1000 when the digital-to-analog converter transitions to an inactive state. However, once the digital-to-analog converter has settled, the switch does not need to remain closed. Utilizing the DAC switching scheme implemented by the switching control circuit 440, the switch of an inactive digital-to-analog converter may be opened once the digital-to-analog converter has settled. By opening the switch, any noise attributable to the first disabled DAC resistor is eliminated. Thus, the resistor noise contribution comes only from the first input resistor 1010 and the first enabled DAC resistor, and the overall contribution to noise from the resistors is reduced to 2Y.

The overall reduction in resistor noise is determined based on the portion of the clock period that the switch remains closed. For example, if the switch is closed for T_{close}, where T_{close} is the portion of a phase of clock cycle (e.g., DAC settling portion 886 of high phase in FIG. 8) for which the switch is closed, the noise contribution of the disabled resistor (e.g., disabled DAC resistor) may be reduced to T_{close}*Y. In one specific example, wherein T_{close} is ⅕, the overall noise attributable to the resistors is reduced from 3Y to 2Y+0.2*Y=2.2Y.

As a further example, consider the introduction of noise due to the operational amplifier 1002. Assuming each of the resistors (e.g., first input resistor 1010, the first enabled DAC resistor, and the first disabled DAC resistor) have the same resistance (R), the noise from the operational amplifier 1002 may be approximated by the equation:

$${N}_{O P} * {( 1 + \frac{R}{\frac{R}{2}} )}^{2}$$

where N_{OP} is the input referred noise of the operational amplifier 1002. Resulting in an overall op-amp noise of 9*N_{OP}. However, when the switch is open, the noise attributable to the disabled resistor (e.g., disabled DAC resistor) is removed. In such an instance, the noise from the operational amplifier 1002 may be approximated by the equation:

$${N}_{O P} * {( 1 + \frac{R}{R} )}^{2}$$

resulting in an overall op-amp noise of 4*N_{OP}. Thus, when the switch is closed, the overall noise attributable to the operational amplifier 1002 is 2.25 times (or 3.5 dB) greater than when the switch is open. Similar to the resistance noise, the overall reduction in op-amp noise is determined based on the portion of the clock period (T_{close}) that the switch remains closed. For example, when T_{close} is ⅕, the overall noise attributable to the op-amp may be approximated by:

$${N}_{O P} * {( 1 + \frac{R}{\frac{5}{6} R} )}^{2} = 4.84 * {N}_{O P}$$

Thus, the overall noise attributable to the op-amps is reduced from 9*N_{OP} to 4.84*N_{OP} wherein T_{close} is ⅕.

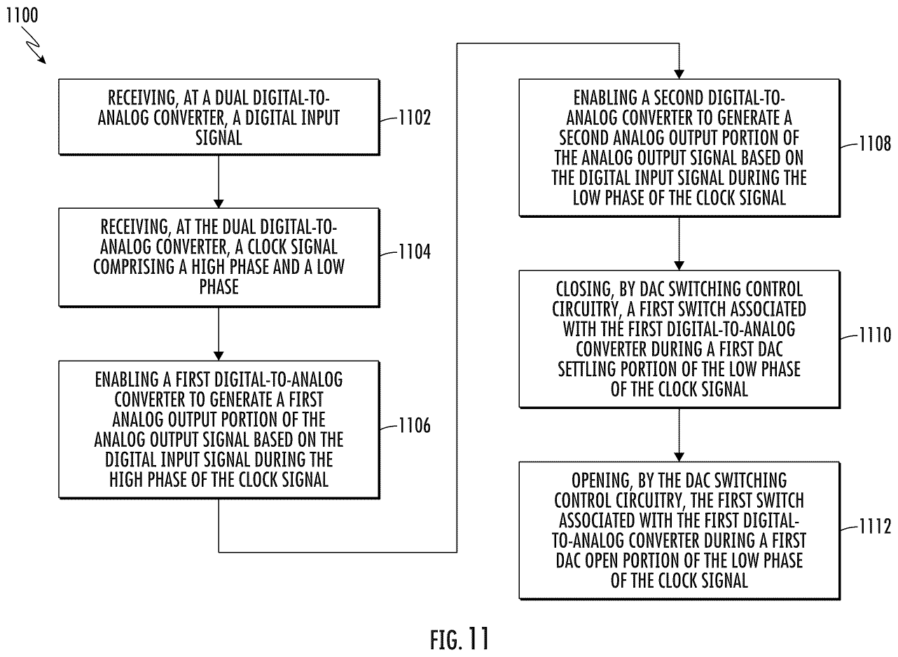

Referring now to FIG. 11, a flowchart 1100 depicting an example process for generating an analog output signal (e.g., analog output signal 110) based on a digital input signal at a dual digital-to-analog converter (e.g., dual digital-to-analog converter 400) is provided.

At block 1102, a digital input signal (e.g., digital signal 108) is received at the dual digital-to-analog converter, wherein the dual digital-to-analog converter comprises a first digital-to-analog converter (e.g., first digital-to-analog converter 102) and a second digital-to-analog converter (e.g., second digital-to-analog converter 104). A digital input signal may be any signal configured to occupy a discrete number of values.

At block 1104, a clock signal (e.g., clock signal 106) comprising a high phase (e.g., high phase 106h) and a low phase (e.g., low phase 106f) is received at the dual digital-to-analog converter.

At block 1106, the dual digital-to-analog converter enables the first digital-to-analog converter to generate a first analog output portion of the analog output signal based on the digital input signal during the high phase of the clock signal. The first digital-to-analog converter may be enabled based on the output of signal generation circuitry (e.g., signal generation circuitry 322) to a control system associated with the first digital-to-analog converter. The first digital-to-analog converter may be configured as such, such that the analog output signal is generated by the first digital-to-analog converter throughout the high phase of the clock signal.

At block 1108, the dual digital-to-analog converter enables the second digital-to-analog converter to generate a second analog output portion of the analog output signal based on the digital input signal during the low phase of the clock signal. The second digital-to-analog converter may be enabled based on the output of signal generation circuitry (e.g., signal generation circuitry 322) to a control system associated with the second digital-to-analog converter. The second digital-to-analog converter may be configured as such, such that the analog output signal is generated by the second digital-to-analog converter throughout the low phase of the clock signal.

At block 1110, the DAC switching control circuit (e.g., DAC switching control circuit 440) of the dual digital-to-analog converter 400 closes the first switch associated with the first digital-to-analog converter during a first DAC settling portion (e.g., first DAC settling portion 882) of the low phase of the clock signal. As described herein, the first digital-to-analog converter may be disabled during the low phase of the clock signal. Closing the first switch settles the voltage difference between the first portion of the first digital-to-analog converter on one side of the first switch (e.g., net point 339a_p) and a second portion of the first digital-to-analog converter on another side of the first switch (e.g., net point 339a_m). The first switch is closed based on a first switch close signal (e.g., first switch close signal 332) and an inverse first switch close signal (e.g., inverse first switch close signal 332n) generated by the DAC switching control circuit. The first switch close signal and the inverse first switch close signal define the first DAC settling portion of the low phase of the clock signal based on a buffer circuit delay (e.g., buffer circuit delay 772) of the DAC switching control circuit.

The first DAC settling portion may be defined based on a settling time associated with the first digital-to-analog converter. While the first switch is closed and the first digital-to-analog converter is disabled, the first digital-to-analog converter may inject unwanted noise into the system. Thus, the amount of time the first switch is closed while the first digital-to-analog converter is disabled should be limited.

At block 1112, the DAC switching control circuit opens the first switch associated with the first digital-to-analog converter during a first DAC open portion of the low phase of the clock signal. The first DAC open portion of the low phase of the clock is associated with the duration of the low phase of the clock for which the first switch is open. The first switch is open based on the first switch close signal and the inverse first switch close signal generated by the DAC switching control circuit. The first switch close signal and the inverse first switch close signal define the first DAC open portion of the low phase of the clock signal based on the remaining portion of the low phase of the clock signal once the DAC switching control circuit opens the first switch.

By closing the shorting switch associated with a digital-to-analog converter in a dual digital-to-analog converter for only a portion of the clock phase for which the digital-to-analog converter is disabled, the dual digital-to-analog converter described herein may reduce the amount of noise injected into a system by a dual digital-to-analog converter. Such reduction in noise may improve the efficiency of an electronic system utilizing the dual digital-to-analog converter, for example, increasing a signal to noise ratio of a generated signal.

While this detailed description has set forth some embodiments of the present invention, the appended claims cover other embodiments of the present invention which differ from the described embodiments according to various modifications and improvements. For example, one skilled in the art may recognize that such principles may be applied to any electronic device requiring conversion of a digital signal to an analog signal using a dual digital-to-analog converter. For example, a continuous time sigma-delta ADC, audio devices, wireless communication systems, radar systems, tuning systems in radio devices, and so on.

Within the appended claims, unless the specific term “means for” or “step for” is used within a given claim, it is not intended that the claim be interpreted under 35 U.S.C. 112, paragraph 6.

Use of broader terms such as “comprises,” “includes,” and “having” should be understood to provide support for narrower terms such as “consisting of,” “consisting essentially of,” and “comprised substantially of” Use of the terms “optionally,” “may,” “might,” “possibly,” and the like with respect to any element of an embodiment means that the element is not required, or alternatively, the element is required, both alternatives being within the scope of the embodiment(s). Also, references to examples are merely provided for illustrative purposes, and are not intended to be exclusive.

1. A dual digital-to-analog converter configured to generate an analog output signal based on a digital input signal, comprising:
a clock signal comprising a high phase and a low phase;
a first digital-to-analog converter, comprising:
a first switch, wherein the first digital-to-analog converter is configured to generate a first analog output portion of the analog output signal based on the digital input signal during the high phase of the clock signal;
a second digital-to-analog converter comprising:
a second switch, wherein the second digital-to-analog converter is configured to generate a second analog output portion of the analog output signal based on the digital input signal during the low phase of the clock signal; and
a DAC switching control circuit configured to close the first switch during a first DAC settling portion of the low phase of the clock signal and open the first switch during a first DAC open portion of the low phase of the clock signal.

2. The dual digital-to-analog converter of claim 1, wherein the DAC switching control circuit is further configured to close the second switch during a second DAC settling portion of the high phase of the clock signal and open the second switch during a second DAC open portion of the high phase of the clock signal.

3. The dual digital-to-analog converter of claim 1, wherein the first DAC settling portion of the low phase of the clock signal is associated with a first settling time.

4. The dual digital-to-analog converter of claim 3, wherein the first settling time is associated with a time required to settle a first voltage on a first side of the first switch with a second voltage on a second side of the first switch.

5. The dual digital-to-analog converter of claim 3, wherein the first settling time is less than one-half of the low phase of the clock signal.

6. The dual digital-to-analog converter of claim 3, wherein the first DAC settling portion of the low phase of the clock signal is based on the clock signal and an inverted and delayed clock signal.

7. The dual digital-to-analog converter of claim 6, wherein the DAC switching control circuit is configured to generate the inverted and delayed clock signal by transmitting the clock signal through buffer circuitry configured to delay the clock signal by a buffer circuit delay.

8. The dual digital-to-analog converter of claim 7, wherein the buffer circuitry comprises an odd number of inverters.

9. The dual digital-to-analog converter of claim 7, the DAC switching control circuit further comprising:
an OR gate configured to generate a first switch close signal, based on a logic OR operation of the clock signal and the inverted and delayed clock signal,
wherein the first switch is closed based on the first switch close signal.

10. The dual digital-to-analog converter of claim 9, the DAC switching control circuit configured to generate an inverse switch close signal based on an inverse of the first switch close signal, wherein the first switch is closed based on the first switch close signal and the inverse switch close signal.

11. A method for generating an analog output signal based on a digital input signal, the method comprising:
receiving, at a dual digital-to-analog converter, the digital input signal,
wherein the dual digital-to-analog converter comprises a first digital-to-analog converter and a second digital-to-analog converter;
receiving, at the dual digital-to-analog converter, a clock signal comprising a high phase and a low phase;
enabling the first digital-to-analog converter to generate a first analog output portion of the analog output signal based on the digital input signal during the high phase of the clock signal;
enabling the second digital-to-analog converter to generate a second analog output portion of the analog output signal based on the digital input signal during the low phase of the clock signal;
closing, by a DAC switching control circuit, a first switch associated with the first digital-to-analog converter during a first DAC settling portion of the low phase of the clock signal; and
opening, by the DAC switching control circuit, the first switch associated with the first digital-to-analog converter during a first DAC open portion of the low phase of the clock signal.

12. The method of claim 11, further comprising:
closing, by the DAC switching control circuit, a second switch associated with the second digital-to-analog converter during a second DAC settling portion of the high phase of the clock signal; and
opening, by the DAC switching control circuit, the second switch associated with the second digital-to-analog converter during a second DAC open portion of the high phase of the clock signal.

13. The method of claim 11, wherein the first DAC settling portion of the low phase of the clock signal is associated with a first settling time.

14. The method of claim 13, wherein the first settling time is associated with a time required to settle a first voltage on a first side of the first switch with a second voltage on a second side of the first switch.

15. The method of claim 14, wherein the first settling time is less than one-half of the low phase of the clock signal.

16. The method of claim 11, further comprising:
generating an inverted and delayed clock signal by transmitting the clock signal through buffer circuitry configured to invert and delay the clock signal by a buffer circuit delay.

17. The method of claim 16, further comprising:
generating a first switch close signal based on a logic OR operation of the clock signal and the inverted and delayed clock signal, wherein the first switch is closed based on the first switch close signal.

18. The method of claim 17, further comprising:
inverting the first switch close signal to generate an inverse switch close signal, wherein the first switch is closed based on the first switch close signal and the inverse switch close signal.

19. A continuous time sigma-delta analog-to-digital converter, comprising:
difference amplifier circuitry configured to receive an analog input signal and a feedback analog signal, and generate an analog difference signal between the analog input signal and the feedback analog signal;
a continuous time loop filter configured to receive the analog difference signal and generate a filtered analog difference signal;
quantization circuitry configured to receive the filtered analog difference signal and generate a digital output based on a comparison of the filtered analog difference signal to a reference voltage; and
a dual digital-to-analog converter configured to generate the feedback analog signal based on the digital output, the dual digital-to-analog converter comprising:
a clock signal comprising a high phase and a low phase;
a first digital-to-analog converter, comprising:
a first switch, wherein the first digital-to-analog converter is configured to generate a first analog output portion of the feedback analog signal based on the digital output during the high phase of the clock signal;
a second digital-to-analog converter comprising:
a second switch, wherein the second digital-to-analog converter is configured to generate a second analog output portion of the feedback analog signal based on the digital output during the low phase of the clock signal; and
a DAC switching control circuit configured to close the first switch during a first DAC settling portion of the low phase of the clock signal and open the first switch during a first DAC open portion of the low phase of the clock signal.

20. The continuous time sigma-delta analog-to-digital converter of claim 19, wherein the DAC switching control circuit is further configured to close the second switch during a second DAC settling portion of the high phase of the clock signal and open the second switch during a second DAC open portion of the high phase of the clock signal.
